(19) United States
(12) Patent Application Publication
(10) Pub. No.: US 2024/0001485 A1
(43) Pub. Date: Jan. 4, 2024

(54) A LASER ETCHING METHOD FOR MEMS PROBES

(71) Applicant: MAXONE SEMICONDUCTOR CO., LTD., Suzhou, Jiangsu (CN)

(72) Inventors: Haichao YU, Suzhou (CN); Ming ZHOU, Suzhou (CN)

(73) Assignee: MAXONE SEMICONDUCTOR CO., LTD., Suzhou, Jiangsu (CN)

(21) Appl. No.: 18/039,570

(22) PCT Filed: Jul. 27, 2021
(86) PCT No.: PCT/CN2021/108764

§ 371 Date: May 31, 2023

(30) Foreign Application Priority Data
Dec. 1, 2020 (CN) 202011382154.3

(51) Int. Cl. B23K 26/046; B23K 26/06; B23K 26/362; B23K 26/08

(52) U.S. Cl. CPC B23K 26/046; B23K 26/0648; B23K 26/362; B23K 26/0861; G01R 1/06744

(57) ABSTRACT

A laser etching method for MEMS probes belongs to the technical field of semiconductor processing and testing; first, the MEMS probe laser etching method performs the parameter calculation to obtain the step angle of the motor according to the etching spacing of the single crystal silicon wafer; then it performs the initial position adjustment to rotate the spiral through-groove plate to the initial position and move the first etching point to the optical axis, and adjust the four-dimensional stage; and then it performs the laser etching and progress judgment; and finally adjusts the four-dimensional stage and the motor, including the downward movement distance, left movement distance and clockwise rotation angle of the four-dimensional stage and the rotation angle of the motor; the MEMS probe laser etching method, combined with the MEMS probe laser etching device, not only has higher etching accuracy, but also continuously adjusts the etching spacing.

### TECHNICAL FIELD

The invention relates to a laser etching method for MEMS probes, which belongs to the technical field of semiconductor processing and testing.

### BACKGROUND OF INVENTION

The probe card is a test interface used to test bare chips. By directly contacting the probes on the probe card with the pads or bumps on the IC chip, the signal of the IC chip is drawn, and then the IC chip is written with the test instrument to input the test signal, so as to realize the testing before the IC chip is packaged.

One of the core structures of the probe card is the probe. At present, the most widely used methods for making probes are bottom-up and top-down.

Bottom-up electroplating method:

CN201010000429.2, A microprobe structure and a manufacturing method thereof, using the lithography, electroplating, planarization and etching techniques of the semiconductor manufacturing process, and replacing the electroplated second sacrificial layer metal with a polymer to successively form a micro-metal structure with two or more layers on a substrate surface with spatial conversion, thereby obtaining a microprobe structure with more than two layers of micro-metal structure. Here, each layer of micro-metal structure is composed of a single material, while micro-metal structure with two or more layers can be composed of the same material and/or different materials. The microprobe structure made by the above-mentioned microprobe structure manufacturing method has the structural design of strengthening the cantilever beam, and is suitable for the components used for testing various electronic components, and can be used as the testing head of the probe card, thereby effectively increasing the testing bandwidth, reducing spacing, and improving side-by-side testing capabilities.

CN201210221177.5, An electroplating process for a probe for an electrical connector, comprising the following processing steps: Step A, pre-treating the probe to remove oil stains; Step B, activating the probe to activate the oxide film on the surface of the probe; Step C, plating a layer of copper film plating on the surface of the probe; Step D, plating a layer of gold film plating on the surface of the copper film plating; Step E, plating a layer of ruthenium film plating on the surface of the gold film plating; Step F, post-treating the surface of the ruthenium film plating, and the surface is sealed, washed and dried. The electroplating process has the advantages of low cost of raw materials, low processing difficulty, low production cost, and meeting the high requirements of the appearance quality of electrical connectors.

CN201710402364.6, An electroplating process that can improve the surface smoothness of a voltage-equalizing electrode probe of a high-voltage direct current converter valve places the pre-treated voltage-equalizing electrode probe into an electroplating solution for platinum-plating treatment. The composition of the electroplating solution is: sodium tetrachloroplatinate or sodium chloroplatinate, ethylenediaminetetraacetic acid disodium salt or tetrasodium tetrasodium ethylenediaminetetraacetate; use the voltage-equalizing electrode probe as the working electrode and the annular platinum sheet as the counter electrode, and place the equalizing electrode probe in the middle of the annular platinum sheet; under the appropriate conditions of electroplating solution temperature, pH value, and electroplating current, the plating layer on the surface of the voltage-equalizing electrode probe is made to a fixed thickness. The electroplating process is simple and easy to control. The chelating agent in the electroplating solution is used to limit the activity of platinum ions and their diffusion coefficient in the electroplating solution, thereby controlling the reduction reaction speed of platinum, and then controlling the surface finish of the platinum deposition layer to achieve a mirror surface.

Since the bottom-up electroplating process uses a large number of chemical raw materials, it will cause environmental problems. More importantly, the electroplating precision is not easy to control, and it is extremely difficult to manufacture micron-sized or even sub-micron-sized probes.

Top-down processing:

First, the probe tape to be processed is bonded to the surface of the wafer, and then a photoresist mask is prepared by a photolithography process, and then a dry or wet process is used for etching to realize the fabrication of small-sized and high-accuracy probes. However, in order to realize the preparation of probes of smaller size and ensure high etching accuracy, the cost of the process equipment used in this process will increase exponentially. Therefore, the production cost of small-sized and high-accuracy probes is extremely high.

In view of the above problems, a probe preparation process based on the laser etching method has emerged. This preparation process can effectively solve the environmental protection problems existing in the bottom-up electroplating method and the high-cost problem existing the top-down lithography method.

As the size of the probe becomes smaller and smaller, the accuracy of laser etching is required to be higher and higher. At the same time, with the continuous emergence of the demand for special probe cards, the structure of the corresponding probe becomes more and more complicated, and the corresponding laser etching pattern becomes irregular, which bring more and more challenges to etching. In order to adapt to this change, a laser etching device with high accuracy and continuous adjustment of spacing is urgently needed. However, based on the understanding of existing materials and instruments, no universal laser etching equipment, method, or key technology capable of achieving the above functions has been found.

### DISCLOSURE OF THE INVENTION

Aiming at the above problems, the present invention discloses a laser etching method for MEMS probes, and with the MEMS probe laser etching device of the present invention, not only the etching accuracy is higher, but also the etching spacing can be continuously adjusted.

The purpose of the invention is achieved in this way:
A MEMS probe laser etching device is sequentially provided with an arc light source, a spiral through-groove plate, a straight through-groove plate, an objective lens, a single crystal silicon wafer, and a four-dimensional stage according to the direction of light propagation;
The distance from each point of the arc light source to the center of the objective lens is the same, that is, the shape of the arc light source is a circular arc with the center of the objective lens as the center of the circle; the tangent of each point of the arc light source is perpendicular to the line connecting the point to the center of the objective lens;
The spiral through-groove plate comprises a first base plate with a spiral through-groove and a first side edge with a circular cross-section, and the outer surface of the side edge is provided with teeth to form a gear structure, and the spiral line of the spiral through-groove satisfies the following relationship:

l(α)=l₀−kα
Wherein: l₀ is the maximum distance between the spiral line and the center of the first base plate, and when the distance from the intersection of the spiral through-groove and the straight through-groove to the center of the first base plate is the maximum distance, the position of the first base plate is defined as the initial position; k is a coefficient with a dimension of length/radian; α is a radian; l(α) represents the distance from the intersection of the spiral through-groove and the straight through-groove to the center of the first base plate after the spiral line rotates α from the initial position;
The straight through-groove plate comprises a second base plate with a straight through-groove and a second side edge with an annular cross-section, and the diameter of the inner circle of the second side edge is larger than the diameter of outer circle of the first side edge, and the upper surface of the second base plate is in close contact with the lower surface of the first base plate;
The upper surface of the single crystal silicon wafer and the second base plate are respectively located on the image plane and the object plane of the objective lens, and the single crystal silicon wafer can complete four-dimensional motion under the bearing of the four-dimensional stage;
The four-dimensional stage can complete three-dimensional translation and one-dimensional rotation, and the rotation is performed in the plane determined by the arc light source and the optical axis.

In the above-mentioned MEMS probe laser etching device, a scraper is arranged around the straight through-groove of the second base plate, and a plurality of annular grooves concentric with the second base plate are arranged on the upper surface of the second base plate and the annular grooves start from and end at the scraper around the straight through-groove; the upper surface of the second base plate is also provided with a straight groove in the radial direction, the annular groove and the straight groove are cross-connected, and the annular groove and the straight groove are filled with lubricating oil, and the lubricating oil is added dropwise between the first side edge and the second side edge.

In the above-mentioned MEMS probe laser etching device, the first side edge is externally meshed with a gear, and the gear is controlled to rotate by a motor, and the motor is connected to a controller, and the controller is connected to a four-dimensional stage.

In the above-mentioned MEMS probe laser etching device, a transmission structure is formed between the first side edge and the gear.

A pinhole structure for MEMS probe laser etching device comprises a spiral through-groove plate and straight through-groove plate;

The spiral through-groove plate comprises a first base plate with a spiral through-groove and a first side edge with a circular cross-section, and the outer surface of the side edge is provided with teeth to form a gear structure, and the spiral line of the spiral through-groove satisfies the following relationship:

l(α)=l₀−kα
Wherein: l₀ is the maximum distance between the spiral line and the center of the first base plate, and when the distance from the intersection of the spiral through-groove and the straight through-groove to the center of the first base plate is the maximum distance, the position of the first base plate is defined as the initial position; k is a coefficient with a dimension of length/radian; α is a radian; l(α) represents the distance from the intersection of the spiral through-groove and the straight through-groove to the center of the first base plate after the spiral line rotates α from the initial position;
The straight through-groove plate comprises a second base plate with a straight through-groove and a second side edge with an annular cross-section, and the diameter of the inner circle of the second side edge is larger than the diameter of outer circle of the first side edge, and the upper surface of the second base plate is in close contact with the lower surface of the first base plate;
The upper surface of the single crystal silicon wafer and the second base plate are respectively located on the image plane and the object plane of the objective lens, and the single crystal silicon wafer can complete four-dimensional motion under the bearing of the four-dimensional stage;
The four-dimensional stage can complete three-dimensional translation and one-dimensional rotation, and the rotation is performed in the plane determined by the arc light source and the optical axis.

A laser etching method for MEMS probes includes the following steps:
Step a: Parameter calculation
According to the etching spacing d of the single crystal silicon wafer, the step angle Δβ of the motor is obtained:

$$Δ β = \frac{d}{k} \cdot \frac{{l}_{1}}{{l}_{2}} \cdot \frac{{d}_{1}}{{d}_{2}}$$

Wherein:
k is the coefficient of the spiral line of the spiral through-groove of the first base plate with the length/radian dimension;
l₁ is the distance from the second base plate to the center of the objective lens;
l₂ is the distance from the upper surface of the single crystal silicon wafer to the center of the objective lens;
d₁ is the diameter of the pitch circle of the first side edge;
d₂ is the diameter of the pitch circle of the gear;
Step b: Initial position adjustment
Step b1: Rotate the spiral through-groove plate to the initial position, and move the first etching point to the optical axis;
Step b2: Four-dimensional stage adjustment:
Move upward:

$$( {h}_{1} + {h}_{2} ) \cdot \frac{\sqrt{{l}_{0}^{2} + {l}_{1}^{2}} - {l}_{1}}{\sqrt{{l}_{0}^{2} + {l}_{1}^{2}}}$$

Move to the right:

$${l}_{0} \cdot \frac{{l}_{2}}{{l}_{1}} + ( {h}_{1} + {h}_{2} ) \cdot \frac{{l}_{0}}{\sqrt{{l}_{0}^{2} + {l}_{1}^{2}}}$$

Rotate counterclockwise:

$$arctan \frac{{l}_{0}}{{l}_{1}}$$

Wherein:
l₀ is the maximum distance between the spiral line and the center of the first base plate;
h₁ is the thickness of the single crystal silicon wafer;
h₂ is the distance from the center of the rotation axis of the four-dimensional stage to the upper surface;
Step c: Laser etching
Light the arc light source until the etching is completed;
Step d: Progress judgment
Judge whether the current etch line is etched, and if:
Yes, the four-dimensional stage moves forward or backward to the next line for etching;
No, go to step e;
Step e: Four-dimensional stage and motor adjustment
Specifically:
The four-dimensional stage moves downward:

(h₁+h₂)·cos γ₂−d·sin γ₂−(h₁+h₂)·cos γ₁
The four-dimensional stage moves to the left;

$$\frac{{l}_{2}}{tan {γ}_{1}} + ( {h}_{1} + {h}_{2} ) \cdot sin {γ}_{1} - \frac{{l}_{2}}{tan {γ}_{2}} - ( {h}_{1} + {h}_{2} ) \cdot sin {γ}_{2} + d \cdot cos {γ}_{2}$$

The four-dimensional stage rotates clockwise:

γ₁−γ₂
The motor rotates:

$$\frac{{d}_{1}}{{d}_{2}} \cdot \frac{{l}_{1}}{k} \cdot ( tan {γ}_{1} - tan {γ}_{2} )$$

Wherein:
γ₁ is the angle between the light beam and the optical axis at the current etching point;
γ₂ is the angle between the light beam and the optical axis at the next etching point;
Return to step c.

The laser etching method for MEMS probes is applied to a MEMS probe laser etching device.

With a MEMS probe laser etching motor and a four-dimensional stage driving method, the step angle of the motor, the upward or downward movement distance, the left or right movement distance, and the clockwise or counterclockwise rotation angle of the four-dimensional stage are obtained from the etching spacing d of a single crystal silicon wafer.

With a MEMS probe laser etching motor and a four-dimensional stage driving method, the etching spacing d of a single crystal silicon wafer, then:
The step angle Δβ of the motor is:

$$Δ β = \frac{d}{k} \cdot \frac{{l}_{1}}{{l}_{2}} \cdot \frac{{d}_{1}}{{d}_{2}}$$

The four-dimensional stage moves upward or downward:

(h₁+h₂)·cos γ₂−d·sin γ₂−(h₁+h₂)·cos γ₁
The four-dimensional stage moves to the left or to the right:

$$\frac{{l}_{2}}{tan {γ}_{1}} + ( {h}_{1} + {h}_{2} ) \cdot sin {γ}_{1} - \frac{{l}_{2}}{tan {γ}_{2}} - ( {h}_{1} + {h}_{2} ) \cdot sin {γ}_{2} + d \cdot cos {γ}_{2}$$

The four-dimensional stage rotates clockwise or counterclockwise:
Wherein:
k is the coefficient of the spiral line of the spiral through-groove of the first base plate with the length/radian dimension;
l₁ is the distance from the second base plate to the center of the objective lens;
l₂ is the distance from the upper surface of the single crystal silicon wafer to the center of the objective lens;
d₁ is the diameter of the pitch circle of the first side edge;
d₂ is the diameter of the pitch circle of the gear;
h₁ is the thickness of the single crystal silicon wafer;
h₂ is the distance from the center of the rotation axis of the four-dimensional stage to the upper surface;
γ₁ is the angle between the light beam and the optical axis at the current etching point;
γ₂ is the angle between the light beam and the optical axis at the next etching point;
The movement direction and rotation direction of the four-dimensional stage are determined by the rotation direction of the motor.

The MEMS probe laser etching motor and the four-dimensional stage driving method are applied to a MEMS probe laser etching device.

The MEMS probe laser etching device uses an optical focusing structure. In the MEMS probe laser etching device, the spiral through-groove plate is replaced by the upper-slotted through-groove plate, and the straight through-groove plate is replaced by the lower-slotted through-groove plate, the single crystal silicon wafer is replaced with a plane mirror of the same thickness, the thickness of the upper-slotted through-groove plate is the same as that of the first base plate of the spiral through-groove plate, the thickness of the lower-slotted through-groove plate is the same as that of the second base plate of the straight through-groove plate, the thickness of the plane mirror is the same as that of the single crystal silicon wafer, and the upper surface of the upper-slotted through-groove plate is in close contact with the lower-slotted through-groove plate; a prism is arranged between the lower-slotted through-groove plate and the objective lens, and an image sensor is arranged on the side edge of the prism. Along the direction of the optical axis, the distance from the lower surface of the lower-slotted through-groove plate to the prism is the same as the distance from the image surface of the image sensor to the prism.

The optical focusing method for MEMS probe laser etching device includes the following steps:
Step a: Replace and add the components
Replacement: In the MEMS probe laser etching device, the spiral through-groove plate is replaced by the upper-slotted through-groove plate, and the straight through-groove plate is replaced by the lower-slotted through-groove plate, and the single crystal silicon wafer is replaced with a plane mirror;
Addition: A prism is arranged between the lower-slotted through-groove plate and the objective lens, and an image sensor is arranged on the side edge of the prism. Along the direction of the optical axis, the distance from the highest point of the arc light source to the prism is the same as the distance from the image surface of the image sensor to the prism;
Step b: Data acquisition
The four-dimensional stage moves upward and downward the full range for one cycle, and obtains a series of focused and defocused spot images on the image sensor, and records the mapping relationship between the position of the four-dimensional stage in the upward and downward direction and the image;
Step c: Data processing
The spot diameter is obtained according to the focused and defocused spot images on the image sensor, and the mapping relationship between the position of the four-dimensional stage in the upward and downward direction and the spot diameter is established;
Step d: Complete the calibration
Determine the minimum value of the spot diameter, and determine the position of the four-dimensional stage in the upward and downward direction corresponding to the minimum value according to the mapping relationship between the position of the four-dimensional stage in the upward and downward direction and the spot diameter, and move the four-dimensional stage to the position.

The above-mentioned MEMS probe laser etching device uses an optical focusing method. In step c, the spot diameter is obtained according to the focused and defocused spot images obtained by the image sensor. It can be achieved by the following method: By setting a grayscale threshold, pixels in the spot image with a grayscale lower than the grayscale threshold are set to 0, and pixels greater than the grayscale threshold are set to 255. Then, the processed image is fitted circumferentially to synthesize a circular spot, and the diameter of the circular spot is determined.

The above-mentioned MEMS probe laser etching device uses an optical focusing method. In step c, the spot diameter is obtained according to the focused and defocused spot images obtained by the image sensor. It can be achieved by the following method: In both the focused and defocused spot images, a fixed area with the center of the light spot as the center is selected, the sum of the grayscale values of all pixels within the fixed area is calculated and the reciprocal of the calculated results is used as the spot diameter.

Beneficial Effects:

First, in the MEMS probe laser etching device of the present invention, since an arc light source is provided, and the distance from each point of the arc light source to the center of the objective lens is the same, that is, the shape of the arc light source is an arc with the center of the objective lens as the center of the circle; the tangent line of each point of the arc light source is perpendicular to the line connecting the point to the center of the objective lens, so it can provide a light beam directly irradiating the pinhole, avoiding the problem of uneven etching depth caused by the uneven energy distribution of the light beam at different positions due to the thickness of the first and second base plates under the special structure of the present invention.

Second, in the MEMS probe laser etching device of the present invention, since the pinhole structure forming the point light source is composed of a spiral through-groove plate and a straight through-groove plate, and the pinhole position is changed by the rotation of the spiral through-groove plate, Under this structure, the pinhole position can be continuously changed to adapt to probes with different etching spacings, and the applicability is wider; more importantly, by matching the exposure time of the arc light source and the rotation step angle of the spiral through-groove plate can realize the dynamic adjustment of the etching spacing, and can etch the probes with any variable spacing.

Third, in the MEMS probe laser etching device of the present invention, the etching depth can be adjusted by changing the energy of the arc light source; the etching speed can be adjusted by changing the rotational speed of the spiral through-groove plate, so as to meet the etching requirements under different parameters.

Fourth, in the MEMS probe laser etching device of the present invention, since the change of the etching position is realized by rotating the spiral through-groove plate, there is only the same roundness error at different positions. Compared with the traditional translation method, there is no accumulation of displacement errors, so in terms of light beam accuracy, it is more conducive to etching with smaller spacing to achieve the high etching accuracy.

Fifth, in the MEMS probe laser etching device of the present invention, although compared with the traditional unidirectional etching method, because the light beam passes through the pinhole from the arc light source, it has different irradiation angles at different positions, but since a four-dimensional stage is provided, and the four-dimensional stage can be adjusted according to the etching position, the vertical etching can be achieved no matter where the pinholes forming the point light source are located, thereby ensuring the etching accuracy.

Sixth, in the MEMS probe laser etching device of the present invention, a special optical focusing structure for the MEMS probe laser etching device is also provided, and an optical focusing method for the MEMS probe laser etching device is designed. The positions of the pinhole structure and the single crystal silicon wafer on the four-dimensional stage can be determined when they're located on the object plane and image plane of the objective lens respectively through the “confocal” setting where the distance from the upper slotted through-groove plate to the prism is the same as the distance from the image surface of the image sensor to the prism and by scanning the light spots at different positions of the four-dimensional stage, so that the entire device can be adjusted before etching to ensure that the relationship between the pinhole structure and the single crystal silicon wafer strictly satisfies the object-image relationship, thereby ensuring the etching accuracy.

Seventh, in the MEMS probe laser etching device of the present invention, the larger the diameter of the pitch circle of the first side edge, the smaller the diameter of the pitch circle of the gear, the higher the accuracy, but the slower the speed, while the smaller the diameter of the pitch circle of the first side edge, the larger the diameter of the pitch circle of the gear, the lower the accuracy, but the higher the speed; the transmission structure is selected for the first side edge and the gear, so that the transmission ratio of the motor to the spiral through-groove plate can be changed, which is conducive to more flexible adjustment of etching speed and accuracy.

### BRIEF DESCRIPTION OF THE DRAWINGS

FIG. 1 is a schematic view 1 of the MEMS probe laser etching device of the present invention.

FIG. 2 is a schematic view 1 of the spiral through-groove plate of the MEMS probe laser etching device of the present invention.

FIG. 3 is a schematic view 1 of the straight through-groove plate of the MEMS probe laser etching device of the present invention.

FIG. 4 is a schematic view of a pinhole formed after a spiral through-groove plate and a straight through-groove plate are superimposed.

FIG. 5 is a schematic view of the second base plate.

FIG. 6 is a schematic view 2 of the MEMS probe laser etching device of the present invention.

FIG. 7 is a flow chart of the MEMS probe laser etching method of the present invention.

FIG. 8 is a schematic view of the relative position of components after the first step of the initial position adjustment process is completed.

FIG. 9 is a relative positional relationship diagram before and after the adjustment of the four-dimensional stage in the second step of the initial position adjustment process.

FIG. 10 is a relative positional relationship diagram before and after the adjustment of the four-dimensional stage between two adjacent etchings.

FIG. 11 is a schematic view of an optical focusing structure for the MEMS probe laser etching device of the present invention.

FIG. 12 is a flow chart of the optical focusing method for the MEMS probe laser etching method of the present invention.

In the figures: 1 arc light source, 2 spiral through-groove plate, 2-1 first base plate, 2-2 first side edge, 3 straight through-groove plate, 3-1 second base plate, 3-2 second side edge, 4 objective lens, 5 single crystal silicon wafer, 6 four-dimensional stage, 7 gear, 8 motor, 9 controller, 10 prism, 11 image sensor, 21 upper slotted through-groove plate, 31 lower slotted through-groove plate, 51 plane mirror.

### SPECIFIC EMBODIMENT

The specific embodiments of the invention are further described in detail below with reference to the figures.

### Specific Embodiment 1

The following is a specific embodiment of the MEMS probe laser etching device of the present invention.

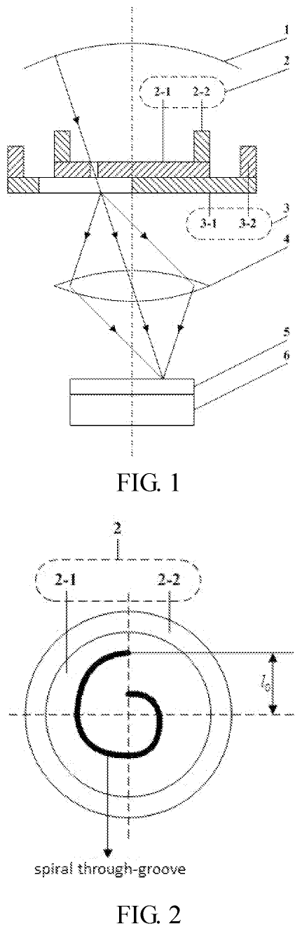

The MEMS probe laser etching device of the embodiment with the schematic view shown in FIG. 1, is sequentially provided with an arc light source 1, a spiral through-groove plate 2, a straight through-groove plate 3, an objective lens 4, a single crystal silicon wafer 5, and a four-dimensional stage 6 according to the direction of light propagation;

The distance from each point of the arc light source 1 to the center of the objective lens 4 is the same, that is, the shape of the arc light source 1 is a circular arc with the center of the objective lens 4 as the center of the circle; the tangent of each point of the arc light source 1 is perpendicular to the line connecting the point to the center of the objective lens 4;

The spiral through-groove plate 2 with the schematic view shown in FIG. 2 comprises a first base plate 2-1 with a spiral through-groove and a first side edge 2-2 with a circular cross-section, and the outer surface of the side edge 2-2 is provided with teeth to form a gear structure, and the spiral line of the spiral through-groove satisfies the following relationship:

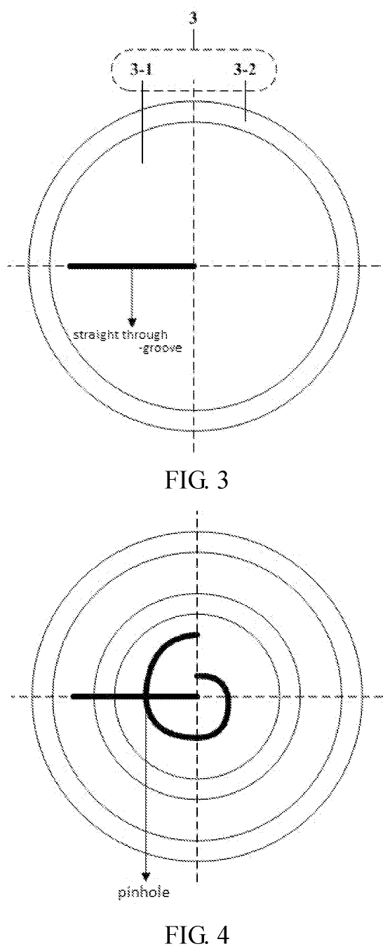

l(α)=l₀−kα
Wherein: l₀ is the maximum distance between the spiral line and the center of the first base plate 2-1, and when the distance from the intersection of the spiral through-groove and the straight through-groove to the center of the first base plate 2-1 is the maximum distance, the position of the first base plate 2-1 is defined as the initial position; k is a coefficient with a dimension of length/radian; α is a radian; l(α) represents the distance from the intersection of the spiral through-groove and the straight through-groove to the center of the first base plate 2-1 after the spiral line rotates α from the initial position;
The straight through-groove plate 3 with the schematic view shown in FIG. 3 comprises a second base plate 3-1 with a straight through-groove and a second side edge 3-2 with an annular cross-section, and the diameter of the inner circle of the second side edge 3-2 is larger than the diameter of outer circle of the first side edge 2-2, and the upper surface of the second base plate 3-1 is in close contact with the lower surface of the first base plate 2-1;
The schematic view of a pinhole formed after a spiral through-groove plate 2 and a straight through-groove plate 3 are superimposed is shown in FIG. 4;
The upper surface of the single crystal silicon wafer 5 and the second base plate 3-1 are respectively located on the image plane and the object plane of the objective lens 4, and the single crystal silicon wafer 5 can complete four-dimensional motion under the bearing of the four-dimensional stage 6;
The four-dimensional stage 6 can complete three-dimensional translation and one-dimensional rotation, and the rotation is performed in the plane determined by the arc light source 1 and the optical axis.

### Specific Embodiment 2

The following is a specific embodiment of the MEMS probe laser etching device of the present invention.

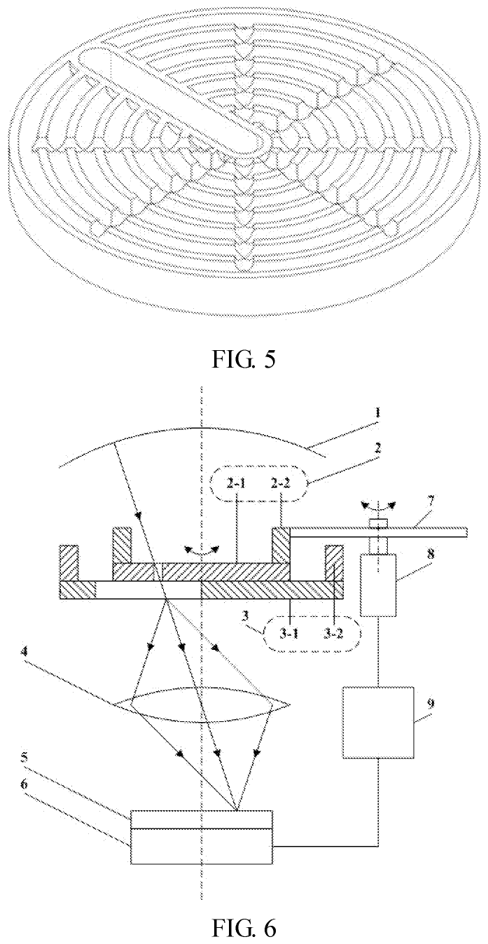

For the EMS probe laser etching device of the embodiment, it is further defined on the basis of the specific embodiment 1: a scraper is arranged around the straight through-groove of the second base plate 3-1, and a plurality of annular grooves concentric with the second base plate 3-1 are arranged on the upper surface of the second base plate 3-1 and the annular grooves start from and end at the scraper around the straight through-groove; the upper surface of the second base plate 3-1 is also provided with a straight groove in the radial direction, the annular groove and the straight groove are cross-connected, and the annular groove and the straight groove are filled with lubricating oil as shown in FIG. 5, and the lubricating oil is added dropwise between the first side edge 2-2 and the second side edge 3-2.

### Specific Embodiment 3

The following is a specific embodiment of the MEMS probe laser etching device of the present invention.

For the EMS probe laser etching device of the embodiment, it is further defined on the basis of the specific embodiment 1 and the specific embodiment 2: In the structure of the MEMS probe laser etching device as shown in FIG. 6, the first side edge 2-2 is externally meshed with a gear 7, and the gear is controlled to rotate by a motor 8, and the motor 8 is connected to a controller 9, and the controller 9 is connected to a four-dimensional stage 6.

### Specific Embodiment 4

The following is a specific embodiment of the MEMS probe laser etching device of the present invention.

For the EMS probe laser etching device of the embodiment, it is further defined on the basis of the specific embodiment 3: a transmission structure is formed between the first side edge 2-2 and the gear 7.

### Specific Embodiment 5

The following is a specific embodiment of the pinhole structure for the MEMS probe laser etching device of the present invention.

The pinhole structure for MEMS probe laser etching device of the embodiment comprises a spiral through-groove plate 2 and straight through-groove plate 3;

The spiral through-groove plate 2 with the schematic view shown in FIG. 2 comprises a first base plate 2-1 with a spiral through-groove and a first side edge 2-2 with a circular cross-section, and the outer surface of the side edge 2-2 is provided with teeth to form a gear structure, and the spiral line of the spiral through-groove satisfies the following relationship:

l(α)=l₀−kα
Wherein: l₀ is the maximum distance between the spiral line and the center of the first base plate 2-1, and when the distance from the intersection of the spiral through-groove and the straight through-groove to the center of the first base plate 2-1 is the maximum distance, the position of the first base plate 2-1 is defined as the initial position; k is a coefficient with a dimension of length/radian; α is a radian; l(α) represents the distance from the intersection of the spiral through-groove and the straight through-groove to the center of the first base plate 2-1 after the spiral line rotates α from the initial position;
The straight through-groove plate 3 with the schematic view shown in FIG. 3 comprises a second base plate 3-1 with a straight through-groove and a second side edge 3-2 with an annular cross-section, and the diameter of the inner circle of the second side edge 3-2 is larger than the diameter of outer circle of the first side edge 2-2, and the upper surface of the second base plate 3-1 is in close contact with the lower surface of the first base plate 2-1;
The schematic view of a pinhole formed after a spiral through-groove plate 2 and a straight through-groove plate 3 are superimposed is shown in FIG. 4;
A scraper is arranged around the straight through-groove of the second base plate 3-1, and a plurality of annular grooves concentric with the second base plate 3-1 are arranged on the upper surface of the second base plate 3-1 and the annular grooves start from and end at the scraper around the straight through-groove; the upper surface of the second base plate 3-1 is also provided with a straight groove in the radial direction, the annular groove and the straight groove are cross-connected, and the annular groove and the straight groove are filled with lubricating oil as shown in FIG. 5, and the lubricating oil is added dropwise between the first side edge 2-2 and the second side edge 3-2.

### Specific Embodiment 6

The following is a specific embodiment of the MEMS probe laser etching method of the present invention.

The MEMS probe laser etching method of the present invention is applied to the MEMS probe laser etching device of the specific embodiments 1, 2, 3 or 4.

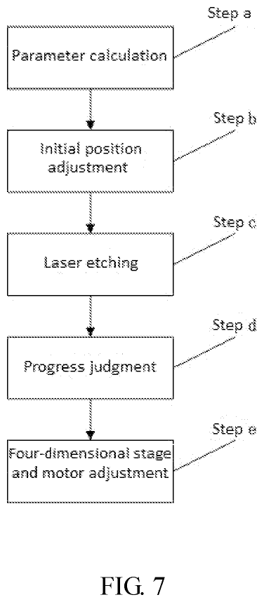

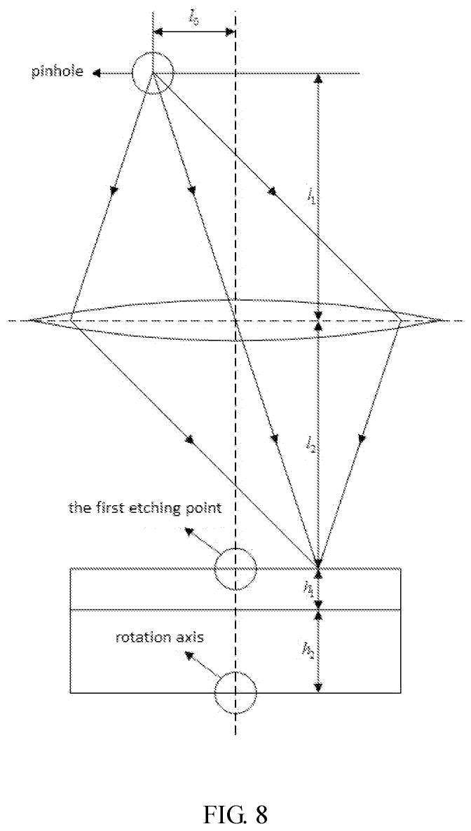

The laser etching method for MEMS probes as shown in flow chart of the FIG. 7 includes the following steps:
Step a: Parameter calculation
According to the etching spacing d of the single crystal silicon wafer 5, the step angle Δβ of the motor 8 is obtained:

$$Δ β = \frac{d}{k} \cdot \frac{{l}_{1}}{{l}_{2}} \cdot \frac{{d}_{1}}{{d}_{2}}$$

Wherein:
k is the coefficient of the spiral line of the spiral through-groove of the first base plate 2-1 with the length/radian dimension;
l₁ is the distance from the second base plate 3-1 to the center of the objective lens 4;
l₂ is the distance from the upper surface of the single crystal silicon wafer 5 to the center of the objective lens 4;
d₁ is the diameter of the pitch circle of the first side edge 2-2;
d₂ is the diameter of the pitch circle of the gear 7;
Step b: Initial position adjustment
Step b1: Rotate the spiral through-groove plate 2 to the initial position, and move the first etching point to the optical axis, as shown in FIG. 8;
Step b2: Four-dimensional stage 6 adjustment:
Move upward:

$$( {h}_{1} + {h}_{2} ) \cdot \frac{\sqrt{{l}_{0}^{2} + {l}_{1}^{2}} - {l}_{1}}{\sqrt{{l}_{0}^{2} + {l}_{1}^{2}}}$$

Move to the right:

$${l}_{0} \cdot \frac{{l}_{2}}{{l}_{1}} + ( {h}_{1} + {h}_{2} ) \cdot \frac{{l}_{0}}{\sqrt{{l}_{0}^{2} + {l}_{1}^{2}}}$$

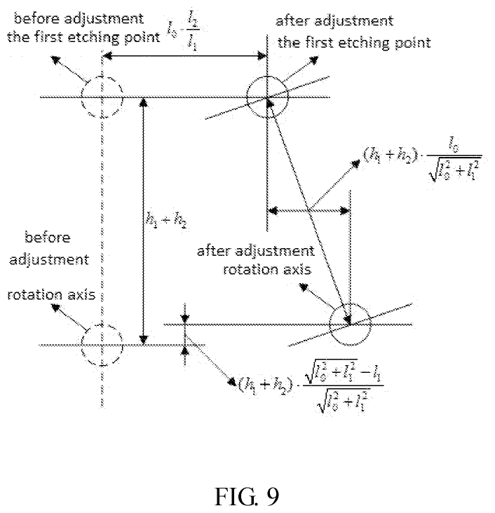

Rotate counterclockwise:

$$arctan \frac{{l}_{0}}{{l}_{1}}$$

Wherein:
l₀ is the maximum distance between the spiral line and the center of the first base plate 2-1;
h₁ is the thickness of the single crystal silicon wafer 5;
h₂ is the distance from the center of the rotation axis of the four-dimensional stage 6 to the upper surface;
The relative positional relationship of four-dimensional stage 6 before and after adjustment is shown in FIG. 9;
Step c: Laser etching
Light the arc light source 1 until the etching is completed;
Step d: Progress judgment
Judge whether the current etch line is etched, and if:
Yes, the four-dimensional stage 6 moves forward or backward to the next line for etching;
No, go to step e;
Step e: Four-dimensional stage 6 and motor 8 adjustment
Specifically:
The four-dimensional stage 6 moves downward:

(h₁+h₂)·cos γ₂−d·sin γ₂−(h₁+h₂)·cos γ₁
The four-dimensional stage 6 moves to the left;

$$\frac{{l}_{2}}{tan {γ}_{1}} + ( {h}_{1} + {h}_{2} ) \cdot sin {γ}_{1} - \frac{{l}_{2}}{tan {γ}_{2}} - ( {h}_{1} + {h}_{2} ) \cdot sin {γ}_{2} + d \cdot cos {γ}_{2}$$

The four-dimensional stage 6 rotates clockwise:

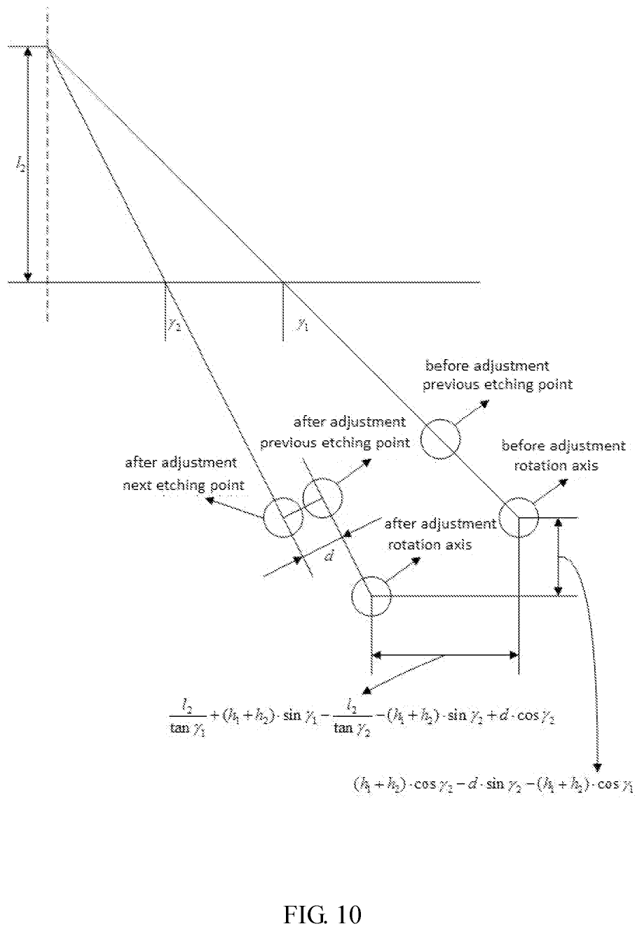

γ₁−γ₂
The motor 8 rotates;

$$\frac{{d}_{1}}{{d}_{2}} \cdot \frac{{l}_{1}}{k} \cdot ( tan {γ}_{1} - tan {γ}_{2} )$$

Wherein:
γ₁ is the angle between the light beam and the optical axis at the current etching point;
γ₂ is the angle between the light beam and the optical axis at the next etching point;
The relative positional relationship diagram before and after the adjustment of the four-dimensional stage between two adjacent etchings is shown in FIG. 10;
Return to step c.

### Specific Embodiment 7

The following is a specific embodiment of the MEMS probe laser etching motor and four-dimensional stage driving method of the present invention.

The MEMS probe laser etching motor and four-dimensional stage driving method of the present invention is applied to the MEMS probe laser etching device of the specific embodiments 1, 2, 3 or 4.

With the MEMS probe laser etching motor and a four-dimensional stage driving method, the step angle of the motor 8, the upward or downward movement distance, the left or right movement distance, and the clockwise or counterclockwise rotation angle of the four-dimensional stage 6 are obtained from the etching spacing d of a single crystal silicon wafer 5.

### Specific Embodiment 8

The following is a specific embodiment of the MEMS probe laser etching motor and four-dimensional stage driving method of the present invention.

The MEMS probe laser etching motor and four-dimensional stage driving method of the present invention is applied to the MEMS probe laser etching device of the specific embodiments 1, 2, 3 or 4; it's further defined on the basis of the specific embodiment 6:

The etching spacing of the single crystal silicon wafer is d, then:

The step angle Δβ of the motor 8 is:

$$Δ β = \frac{d}{k} \cdot \frac{{l}_{1}}{{l}_{2}} \cdot \frac{{d}_{1}}{{d}_{2}}$$

The four-dimensional stage 6 moves upward or downward:

(h₁+h₂)·cos γ₂−d·sin γ₂−(h₁+h₂)·cos γ₁

The four-dimensional stage 6 moves to the left or to the right:

$$\frac{{l}_{2}}{tan {γ}_{1}} + ( {h}_{1} + {h}_{2} ) \cdot sin {γ}_{1} - \frac{{l}_{2}}{tan {γ}_{2}} - ( {h}_{1} + {h}_{2} ) \cdot sin {γ}_{2} + d \cdot cos {γ}_{2}$$

The four-dimensional stage 6 rotates clockwise or counterclockwise:

γ₁−γ₂
Wherein:
k is the coefficient of the spiral line of the spiral through-groove of the first base plate 2-1 with the length/radian dimension;
l₁ is the distance from the second base plate 3-1 to the center of the objective lens 4;
l₂ is the distance from the upper surface of the single crystal silicon wafer 5 to the center of the objective lens 4;

d₁ is the diameter of the pitch circle of the first side edge 2-2;

d₂ is the diameter of the pitch circle of the gear 7;

h₁ is the thickness of the single crystal silicon wafer 5;

h₂ is the distance from the center of the rotation axis of the four-dimensional stage 6 to the upper surface;
γ₁ is the angle between the light beam and the optical axis at the current etching point;
γ₂ is the angle between the light beam and the optical axis at the next etching point;
The relative positional relationship diagram before and after the adjustment of the four-dimensional stage between two adjacent etchings is shown in FIG. 10;
The movement direction and rotation direction of the four-dimensional stage 6 are determined by the rotation direction of the motor 8.

### Specific Embodiment 9

The following is a specific embodiment of the optical focusing structure for the MEMS probe laser etching device of the present invention.

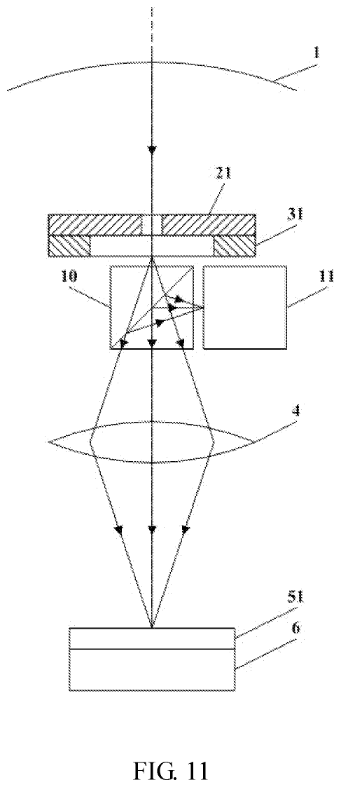

The optical focusing structure for the MEMS probe laser etching device of the embodiment is based on the MEMS probe laser etching device of the specific embodiment 1, 2, 3 or 4. In the MEMS probe laser etching device, the spiral through-groove plate 2 is replaced by the upper-slotted through-groove plate 21, and the straight through-groove plate 3 is replaced by the lower-slotted through-groove plate 31, the single crystal silicon wafer 5 is replaced with a plane mirror 51 of the same thickness, the thickness of the upper-slotted through-groove plate 21 is the same as that of the first base plate 2-1 of the spiral through-groove plate 2, the thickness of the lower-slotted through-groove plate 31 is the same as that of the second base plate 3-1 of the straight through-groove plate 3, the thickness of the plane mirror 51 is the same as that of the single crystal silicon wafer 5, and the upper surface of the upper-slotted through-groove plate 21 is in close contact with the lower-slotted through-groove plate 31; a prism 10 is arranged between the lower-slotted through-groove plate 31 and the objective lens 4, and an image sensor 11 is arranged on the side edge of the prism 10. Along the direction of the optical axis, the distance from the lower surface of the lower-slotted through-groove plate 31 to the prism 10 is the same as the distance from the image surface of the image sensor 11 to the prism 10, with the schematic view shown in FIG. 11. It should be noted that FIG. 11 is based on the MEMS probe laser etching device shown in FIG. 1.

### Specific Embodiment 10

The following is a specific embodiment of the optical focusing method for the MEMS probe laser etching device of the present invention.

The optical focusing method for the MEMS probe laser etching device of the embodiment 9 is applied to the optical focusing structure for the MEMS probe laser etching device of the specific embodiment 9.

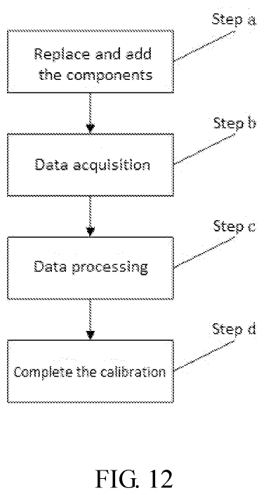

The optical focusing method for MEMS probe laser etching device as shown in the flow chart of FIG. 12 includes the following steps:
Step a: Replace and add the components
Replacement: In the MEMS probe laser etching device, the spiral through-groove plate 2 is replaced by the upper-slotted through-groove plate 21, and the straight through-groove plate 3 is replaced by the lower-slotted through-groove plate 31, and the single crystal silicon wafer 5 is replaced with a plane mirror 51;
Addition: A prism 10 is arranged between the lower-slotted through-groove plate 31 and the objective lens 4, and an image sensor 11 is arranged on the side edge of the prism 10. Along the direction of the optical axis, the distance from the highest point of the arc light source 1 to the prism 10 is the same as the distance from the image surface of the image sensor 11 to the prism
Step b: Data acquisition
The four-dimensional stage 6 moves upward and downward the full range for one cycle, and obtains a series of focused and defocused spot images on the image sensor 11, and records the mapping relationship between the position of the four-dimensional stage 6 in the upward and downward direction and the image;
Step c: Data processing
The spot diameter is obtained according to the focused and defocused spot images on the image sensor 11, and the mapping relationship between the position of the four-dimensional stage 6 in the upward and downward direction and the spot diameter is established;
Step d: Complete the calibration
Determine the minimum value of the spot diameter, and determine the position of the four-dimensional stage 6 in the upward and downward direction corresponding to the minimum value according to the mapping relationship between the position of the four-dimensional stage 6 in the upward and downward direction and the spot diameter, and move the four-dimensional stage 6 to the position.

### Specific Embodiment 11

The following is a specific embodiment of the optical focusing method for the MEMS probe laser etching device of the present invention.

The optical focusing method for the MEMS probe laser etching device of the embodiment is further defined on the basis of the specific embodiment 10: In step c, the spot diameter is obtained according to the focused and defocused spot images obtained by the image sensor 11. It can be achieved by the following method: By setting a grayscale threshold, pixels in the spot image with a grayscale lower than the grayscale threshold are set to 0, and pixels greater than the grayscale threshold are set to 255. Then, the processed image is fitted circumferentially to synthesize a circular spot, and the diameter of the circular spot is determined.

### Specific Embodiment 12

The following is a specific embodiment of the optical focusing method for the MEMS probe laser etching device of the present invention.

The optical focusing method for the MEMS probe laser etching device of the embodiment is further defined on the basis of the specific embodiment 10: In step c, the spot diameter is obtained according to the focused and defocused spot images obtained by the image sensor 11. It can be achieved by the following method: In both the focused and defocused spot images, a fixed area with the center of the light spot as the center is selected, the sum of the grayscale values of all pixels within the fixed area is calculated and the reciprocal of the calculated results is used as the spot diameter.

Finally, it should be noted that the technical features in all the above specific embodiments can be permuted and combined as long as they are not contradictory. Those skilled in the art can exhaust every permutation and combination according to the mathematical knowledge of permutation and combination learned in high school. The results after all the permutations and combinations should be understood as being disclosed by this application.

1. A laser etching method for MEMS probes, wherein: it includes the following steps:
Step a: Parameter calculation
According to the etching spacing d of the single crystal silicon wafer (5), the step angle Δβ of the motor (8) is obtained:
$$Δ β = \frac{d}{k} \cdot \frac{{l}_{1}}{{l}_{2}} \cdot \frac{{d}_{1}}{{d}_{2}}$$
Wherein:
k is the coefficient of the spiral line of the spiral through-groove of the first base plate (2-1) with the length/radian dimension;
l₁ is the distance from the second base plate (3-1) to the center of the objective lens (4);
l₂ is the distance from the upper surface of the single crystal silicon wafer (5) to the center of the objective lens (4);
d₁ is the diameter of the pitch circle of the first side edge (2-2);
d₂ is the diameter of the pitch circle of the gear (7);
Step b: Initial position adjustment
Step b1: Rotate the spiral through-groove plate (2) to the initial position, and move the first etching point to the optical axis;
Step b2: Four-dimensional stage (6) adjustment:
Move upward:
$$( {h}_{1} + {h}_{2} ) \cdot \frac{\sqrt{{l}_{0}^{2} + {l}_{1}^{2}} - {l}_{1}}{\sqrt{{l}_{0}^{2} + {l}_{1}^{2}}}$$
Move to the right:
$${l}_{0} \cdot \frac{{l}_{2}}{{l}_{1}} + ( {h}_{1} + {h}_{2} ) \cdot \frac{{l}_{0}}{\sqrt{{l}_{0}^{2} + {l}_{1}^{2}}}$$
Rotate counterclockwise:
$$arctan \frac{{l}_{0}}{{l}_{1}}$$
Wherein:
l₀ is the maximum distance between the spiral line and the center of the first base plate (2-1);
h₁ is the thickness of the single crystal silicon wafer (5);
h₂ is the distance from the center of the rotation axis of the four-dimensional stage (6) to the upper surface;
Step c: Laser etching
Light the arc light source (1) until the etching is completed;
Step d: Progress judgment
Judge whether the current etch line is etched, and if:
Yes, the four-dimensional stage (6) moves forward or backward to the next line for etching;
No, go to step e;
Step e: Four-dimensional stage (6) and motor (8) adjustment
Specifically:
The four-dimensional stage (6) moves downward:
(h₁+h₂)·cos γ₂−d·sin γ₂−(h₁+h₂)·cos γ₁
The four-dimensional stage (6) moves to the left;
$$\frac{{l}_{2}}{tan {γ}_{1}} + ( {h}_{1} + {h}_{2} ) \cdot sin {γ}_{1} - \frac{{l}_{2}}{tan {γ}_{2}} - ( {h}_{1} + {h}_{2} ) \cdot sin {γ}_{2} + d \cdot cos {γ}_{2}$$
The four-dimensional stage (6) rotates clockwise:
γ₁−γ₂
The motor (8) rotates;
$$\frac{{d}_{1}}{{d}_{2}} \cdot \frac{{l}_{1}}{k} \cdot ( tan {γ}_{1} - tan {γ}_{2} )$$
Wherein:
γ₁ is the angle between the light beam and the optical axis at the current etching point;
γ₂ is the angle between the light beam and the optical axis at the next etching point;
Return to step c.

2. The laser etching method for MEMS probes according to the claim 1, wherein: it is applied to a MEMS probe laser etching device.

3. The laser etching method for MEMS probes according to the claim 2, wherein: the MEMS probe laser etching device is sequentially provided with an arc light source (1), a spiral through-groove plate (2), a straight through-groove plate (3), an objective lens (4), a single crystal silicon wafer (5), and a four-dimensional stage (6) according to the direction of light propagation;
The distance from each point of the arc light source (1) to the center of the objective lens (4) is the same, that is, the shape of the arc light source (1) is a circular arc with the center of the objective lens (4) as the center of the circle; the tangent of each point of the arc light source (1) is perpendicular to the line connecting the point to the center of the objective lens (4);
The spiral through-groove plate (2) comprises a first base plate (2-1) with a spiral through-groove and a first side edge (2-2) with a circular cross-section, and the outer surface of the side edge (2-2) is provided with teeth to form a gear structure, and the spiral line of the spiral through-groove satisfies the following relationship:
l(α)=l₀−kα
Wherein: l₀ is the maximum distance between the spiral line and the center of the first base plate (2-1), and when the distance from the intersection of the spiral through-groove and the straight through-groove to the center of the first base plate (2-1) is the maximum distance, the position of the first base plate (2-1) is defined as the initial position; k is a coefficient with a dimension of length/radian; α is a radian; l(α) represents the distance from the intersection of the spiral through-groove and the straight through-groove to the center of the first base plate (2-1) after the spiral line rotates α from the initial position;
The straight through-groove plate (3) comprises a second base plate (3-1) with a straight through-groove and a second side edge (3-2) with an annular cross-section, and the diameter of the inner circle of the second side edge (3-2) is larger than the diameter of outer circle of the first side edge (2-2), and the upper surface of the second base plate (3-1) is in close contact with the lower surface of the first base plate (2-1);
The upper surface of the single crystal silicon wafer (5) and the second base plate (3-1) are respectively located on the image plane and the object plane of the objective lens (4), and the single crystal silicon wafer (5) can complete four-dimensional motion under the bearing of the four-dimensional stage (6);
The four-dimensional stage (6) can complete three-dimensional translation and one-dimensional rotation, and the rotation is performed in the plane determined by the arc light source (1) and the optical axis.
